(19) United States
(12) Patent Application Publication
(10) Pub. No.: US 2024/0087918 A1
(43) Pub. Date: Mar. 14, 2024

(54) SUBSTRATE PROCESSING APPARATUS, SUBSTRATE PROCESSING METHOD, AND SEMICONDUCTOR DEVICE MANUFACTURING METHOD

(71) Applicant: Kioxia Corporation, Tokyo (JP)

(72) Inventors: Tomohiko SUGITA, Yokkaichi Mie (JP); Hiroshi FUJITA, Mie Mie (JP); Tatsuhiko KOIDE, Kuwana Mie (JP); Katsuhiro SATO, Yokkaichi Mie (JP)

(21) Appl. No.: 18/458,034

(22) Filed: Aug. 29, 2023

(30) Foreign Application Priority Data
Sep. 13, 2022 (JP) 2022-145084

(51) Int. Cl. H01L 21/67; H01L 21/311

(52) U.S. Cl. CPC H01L 21/67086; H01L 21/31111

(57) ABSTRACT

According to one embodiment, a substrate processing apparatus has a treatment tank, a holder to hold the substrate while in the treatment tank, a chemical discharge pipe below a position of the holder for supplying a chemical solution to the treatment tank, a bubble discharge pipe below the position of the holder for discharging a gas. The first bubble discharge pipe is closer along a horizontal direction to a centerline of the treatment tank than is the chemical discharge pipe. A rectifying plate is disposed below the position of the holder and extends from a position above the chemical discharge pipe to a position above the first bubble discharge pipe at an incline with respect to the first direction horizontal.

### CROSS-REFERENCE TO RELATED APPLICATION(S)

This application is based upon and claims the benefit of priority from Japanese Patent Application No. 2022-145084, filed Sep. 13, 2022, the entire contents of which are incorporated herein by reference.

### FIELD

Embodiments described herein relate generally to a substrate processing apparatus, a substrate processing method, and a semiconductor device manufacturing method.

### BACKGROUND

In some cases, a silicon nitride film is selectively etched with respect to a silicon oxide film, on a substrate having a stacked body in which the silicon nitride film and the silicon oxide film are alternately formed. In this case, a phosphoric acid solution is often used as an etchant. In such an etching process, as a silicon compound is added to the phosphoric acid solution, the concentration of silica in the phosphoric acid solution increases, and the selection ratio (selectivity) of the silicon nitride film relative to the silicon oxide film in the etching process can be increased. If the concentration of silica in the phosphoric acid solution is low, then the selection ratio of the silicon nitride film to the silicon oxide film is also low, and the silicon oxide film may be eroded disadvantageously. On the other hand, when the concentration of silica in the phosphoric acid solution is high, silica is likely to become saturated in the etchant solution, and silica may precipitate out of solution on the substrate from the phosphoric acid solution.

In order to control the concentration of silica in the phosphoric acid solution, it is necessary to make the phosphoric acid solution in which the substrate is immersed more uniform during the process.

### BRIEF DESCRIPTION OF THE DRAWINGS

FIG. 1 is a diagram schematically showing the overall configuration of a substrate processing apparatus according to an embodiment.

FIG. 2 is a schematic diagram showing an internal structure of an inner tank according to an embodiment.

FIG. 3 is a perspective view schematically showing the structure of a chemical discharge pipe.

FIG. 4 is a cross-sectional view of a substrate to be etched.

FIG. 5 is a schematic diagram showing an internal structure of an inner tank according to an embodiment.

FIG. 6 is a schematic diagram showing an internal structure of an inner tank according to an embodiment.

FIG. 7 is a schematic diagram showing an internal structure of an inner tank according to an embodiment.

FIG. 8 is a schematic diagram showing an internal structure of an inner tank according to an embodiment.

FIG. 9 is a schematic diagram showing an internal structure of an inner tank according to an embodiment.

FIG. 10 is a schematic diagram showing an internal structure of an inner tank according to an embodiment.

FIG. 11 is a schematic diagram showing an internal structure of an inner tank according to an embodiment.

FIG. 12 is a schematic diagram showing an internal structure of an inner tank according to a modification example.

### DETAILED DESCRIPTION

Embodiments provide a substrate processing apparatus, a substrate processing method, and a semiconductor device manufacturing method in which the efficiency of stirring a processing liquid is improved.

In general, according to one embodiment, a substrate processing apparatus includes a treatment tank, a holder to hold the substrate while in the treatment tank, a chemical discharge pipe below a position of the holder for supplying a chemical solution to the treatment tank, a bubble discharge pipe below the position of the holder for discharging a gas. The first bubble discharge pipe is closer along a horizontal direction to a centerline of the treatment tank than is the chemical discharge pipe. A rectifying plate is disposed below the position of the holder and extends from a position above the chemical discharge pipe to a position above the first bubble discharge pipe at an incline with respect to the first direction horizontal.

Hereinafter, a substrate processing apparatus, a substrate processing method, and a semiconductor device manufacturing method according to certain example embodiments of the present disclosure will be specifically described with reference to the drawings. In the following description, elements having substantially the same functions and configurations are given the same reference numerals, and description of such aspects will not necessarily be described repeatedly. In some descriptions, distinguishing suffixes may be appended to base reference numerals to distinguish being multiple instances of the same element or component type. Each embodiment described below exemplifies an apparatus and a method embodying the technical idea of this present disclosure. However, various modifications may be made to these embodiments without departing from the scope of the present disclosure.

In the drawings, in order to make the description clearer, the width, thickness, shape, or the like of each part may be schematically represented compared to the actual aspects, but this is only an example and does not limit the interpretation of the present disclosure.

In the present specification, the expression that “a includes A, B or C” does not exclude the case where a includes any combination of A, B, and/or C unless otherwise specified. Further, these expressions do not exclude the case where a includes other elements in addition to A, B, or C (or combinations thereof).

In the present specification, “horizontal” may refer to a direction (XY direction) horizontal to the bottom surface of the inner tank, and “vertical” may refer to a direction (Z direction) substantially perpendicular to this horizontal direction.

Each of the following embodiments and modification examples may be combined with each other as long as there is no technical contradiction.

### First Embodiment

### Substrate Processing Apparatus

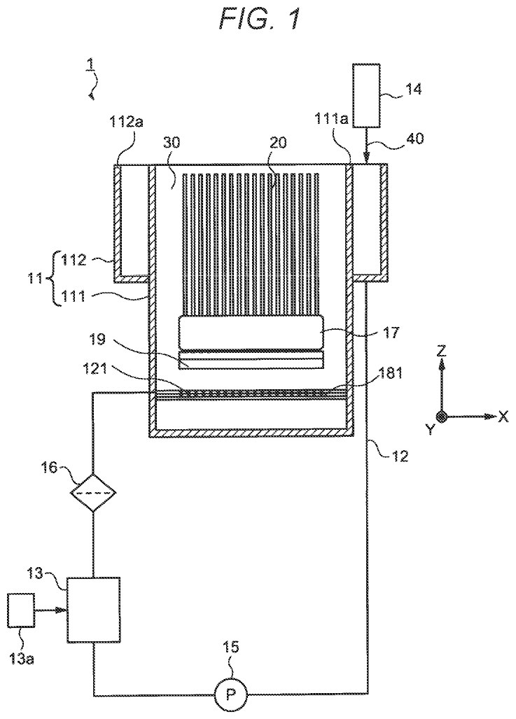

FIG. 1 is a diagram schematically showing the overall configuration of a substrate processing apparatus according to an embodiment. A substrate processing apparatus 1 is a wet etching processing apparatus that removes (etches), for example, a silicon nitride film (not shown in FIG. 1) provided on a substrate 20. A solution 30 containing phosphoric acid (hereinafter referred to as a phosphoric acid solution) can be used in this removal process. As shown in FIG. 1, the substrate processing apparatus 1 includes a treatment tank 11, a circulation path 12, a heating unit 13, an input unit 14, a pump 15, a filter 16, a holding member 17, a bubble discharge pipe 181, and a rectifying plate 19.

The treatment tank 11 is a container having an inner tank 111 and an outer tank 112. The inner tank 111 is formed in a box shape having an upper end opening 111a. The inner tank 111 stores therein a phosphoric acid solution 30, which serves as an etchant (processing liquid) for a silicon nitride film on the immersed substrates 20. The temperature, phosphoric acid concentration, and silica concentration of the phosphoric acid solution 30 stored inside the inner tank 111 are to be optimized for etching the silicon nitride film provided on the substrate 20.

The inner tank 111 can accommodate a wafer-shaped (disc-shaped) substrate 20 vertically (with its main surface parallel to the vertical direction (YZ direction)). Inside the inner tank 111, the holding member 17 can accommodate the substrates 20 arranged in rows in the horizontal direction (X direction) at predetermined intervals. The holding member 17 is, for example, a holder. For example, in FIG. 1, the holding member 17 holds eighteen (18) substrates 20 in the inner tank 111. In general, the number of substrates 20 held in the inner tank 111 is not a limitation. For example, fifty (50) substrates 20 may be accommodated in one inner tank 111.

The holding member 17 may include an elevating mechanism (for example, a lift not shown in FIG. 1) for elevating (lifting) the held substrates 20 in the vertical direction (Z direction) from the inner tank 111. By operation of the elevating mechanism, the substrate 20 can be automatically immersed in the phosphoric acid solution 30 stored in the inner tank 111, and then the substrate 20 after the etching process can be automatically taken out from the inner tank 111.

When the substrate 20 is immersed in the phosphoric acid solution 30, the silicon nitride film provided on the substrate 20 is dissolved in the phosphoric acid solution 30 and thus removed from the substrate 20. Therefore, the inner tank 111 has a depth sufficient to completely immerse the substrates 20 accommodated vertically in the phosphoric acid solution 30. The upper end opening 111a of the inner tank 111 is higher than the upper end portion of the vertically accommodated substrates 20. It is preferable that the distance from the upper end opening 111a of the inner tank 111 to the upper end portion of the vertically accommodated substrates 20 is 3 cm or more.

The outer tank 112 has an upper end opening 112a that surrounds the upper end opening 111a of the inner tank 111 over the entire circumference. The outer tank 112 collects phosphoric acid solution 30 overflowing the upper end opening 111a from the inner tank 111.

The circulation path 12 connects the bottom portion of the outer tank 112 and the bottom portion of the inner tank 111 to circulate the phosphoric acid solution 30 through the entire treatment tank 11. Specifically, the circulation path 12 recirculates the phosphoric acid solution 30 that has flowed in to the outer tank 112 from the inner tank 111 after being supplied to inner tank 111 from a chemical discharge pipe 121. During this recirculation procedure, the phosphoric acid solution 30 passes through the heating unit 13, the pump 15, and the filter 16.

The heating unit 13 is provided in the circulation path 12. The heating unit 13 heats the phosphoric acid solution 30. The heating unit 13 is, for example, a line heater using a halogen lamp as a heat source.

In the present embodiment, the heating control unit 13a adjusts the heating temperature of the heating unit 13 so that the phosphoric acid solution 30 is heated to reach a constant temperature. The phosphoric acid solution 30 (which may be referred to in this context as a heating solution) that has been heated by the heating unit 13 is supplied to the inside of the inner tank 111 after passing through the filter 16.

The input unit 14 is disposed above the outer tank 112. The input unit 14 supplies water into the outer tank 112. The concentration of the phosphoric acid solution 30 collected in the outer tank 112 may have changed due to the evaporation of water while in the inner tank 111 and during the etching process. Therefore, in order to adjust the concentration of the phosphoric acid solution 30 to be recirculated to the inner tank 111 to the optimum concentration for selective etching of the silicon nitride film, water 40 is input from the input unit 14 as necessary.

The input unit 14 may also input phosphoric acid into the outer tank 112 instead of water 40 for the concentration adjustment as necessary. Alternatively, the input unit 14 may supply a phosphoric acid solution that has been adjusted in advance to the optimum concentration for etching the silicon nitride film, that is, the same phosphoric acid concentration as the phosphoric acid solution 30 initially stored in the inner tank 111 (the phosphoric acid solution 30 before the heating solution is returned). In the present embodiment, the temperature of water, phosphoric acid, or the phosphoric acid solution is preferably lower than the temperature of the phosphoric acid solution 30 stored in the inner tank 111 so that a phenomenon referred to as “bumping” does not occur in the outer tank 112.

The pump 15 is provided upstream on the circulation path 12 from the heating unit 13. The phosphoric acid solution 30 collected in the outer tank 112 moves to the heating unit 13 by the pump 15 pulling the phosphoric acid solution 30 from the outer tank 112. The phosphoric acid solution 30 is supplied to the inner tank 111 by the pump 15 after being heated by the heating unit 13.

The filter 16 is provided downstream on the circulation path 12 from the heating unit 13. The filter 16 removes particles contained in phosphoric acid solution 30. The particles include, for example, silica particles formed from dissolved (etched) materials in the phosphoric acid solution 30 from the substrate 20. The filter 16 may be provided upstream from the heating unit 13 in some examples.

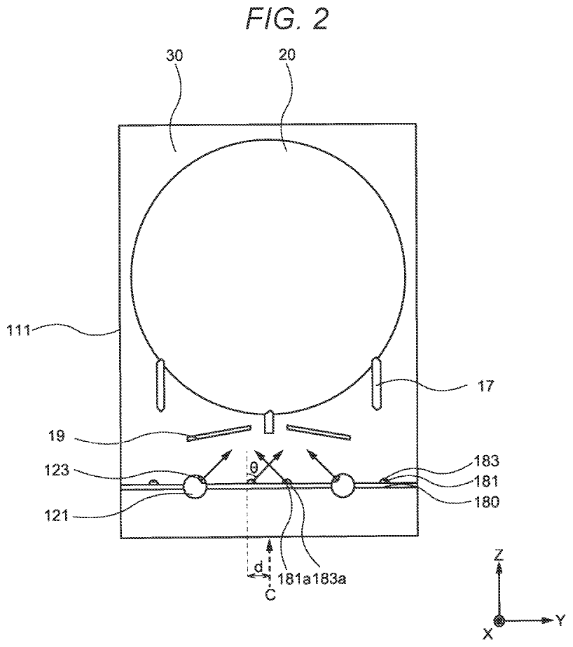

FIG. 2 is a schematic diagram showing the internal structure of the inner tank 111 according to the present embodiment. As shown in FIG. 2, the holding member 17 holds the substrate 20. A tube plate 180 is provided inside the inner tank 111 below the holding member 17 (near the bottom surface of the inner tank 111). The tube plate 180 is a plate-like member disposed substantially horizontally near the bottom portion of the inner tank 111. The tube plate 180 holds a bubble discharge pipe 181 (or bubble discharge pipes 181 including a bubble discharge pipe 181a) and a chemical discharge pipe 121 on the surface (upper surface) facing towards the holding member 17. However, the present disclosure is not limited to this, and the bubble discharge pipe 181 and the chemical discharge pipe 121 may be disposed anywhere below the holding member 17. Similarly, the shape of the tube plate 180 is not particularly limited, and the tube plate 180 may be omitted in some examples.

The chemical discharge pipe 121 is included on the exit side of the circulation path 12 and has a chemical discharge port 123 for supplying the phosphoric acid solution 30 to the inner tank 111. Each chemical discharge pipe 121 extends lengthwise in the X direction. For example, the chemical discharge pipe 121 may extend from one side surface of the inner tank 111 to the opposite side surface thereof in the X direction. However, the present disclosure is not limited to this, and the length of the chemical discharge pipe 121 in the X direction may be the same as the length of the holding member 17. Although two chemical discharge pipes 121 are shown in FIG. 2, the number of chemical discharge pipes 121 is not particularly limited. A plurality of chemical discharge pipes 121 can be in rows spaced the lateral direction (Y direction) of the main surface of the substrate 20. The plurality of chemical discharge pipes 121 may be disposed symmetrically in the Y direction from a center C (midpoint or centerline) in the lateral direction (Y direction) of the main surface of the substrate 20.

The flow rate of the phosphoric acid solution 30 supplied from the chemical discharge pipe 121 is preferably 10 L/min or more into inner tank 111. It is preferable that the chemical discharge pipes 121 are evenly disposed with respect to the substrates 20. In this case, each chemical discharge pipe 121 may supply the phosphoric acid solution 30 at substantially the same flow rate to the inner tank 111. However, the present disclosure is not limited to this, and each chemical discharge pipe 121 may supply the phosphoric acid solution 30 to the inner tank 111 at a different flow rate depending on its arrangement and position with respect to the substrates 20.

The bubble discharge pipe 181 includes bubble discharge ports 183 for supplying bubbles (gas) to stir the phosphoric acid solution 30 stored in the inner tank 111 (the bubble discharge ports 183 includes a bubble discharge port 183a). The bubbles supplied by the bubble discharge pipe 181 may contain, for example, nitrogen. The bubble discharge pipe 181 extends lengthwise in the X direction). For example, the bubble discharge pipe 181 may extend from one side surface of the inner tank 111 to the opposite side surface thereof in the X direction. However, the present disclosure is not limited to this, and the length of the bubble discharge pipe 181 in the X direction may be the same as the length of the holding member 17. Although four bubble discharge pipes 181 are shown in FIG. 2, the number of bubble discharge pipes 181 is not particularly limited. The plurality of bubble discharge pipes 181 are arranged in rows spaced from each other in the lateral direction (Y direction) of the main surface of the substrate 20. The plurality of bubble discharge pipes 181 may be disposed symmetrically about the center C in the lateral direction (Y direction) of the main surface of the substrate 20. Some of the bubble discharge pipes 181 (such as bubble discharge pipes 181a) may be disposed closer to the center C than any of the chemical discharge pipe 121. Some of the bubble discharge pipes 181a may be disposed within a distance d of 2.5 cm from the center C in the lateral direction (Y direction). That is, each bubble discharge pipe 181a may be disposed within a distance d of 2.5 cm from the center C in the lateral direction (Y direction).

The bubble discharge pipe 181 and the chemical discharge pipe 121 may be disposed at the same height inside the inner tank 111. In other examples, the bubble discharge pipe 181 may be disposed above (farther from the bottom of the inner tank 111 than) the chemical discharge pipe 121. When a bubble discharge pipe 181 is disposed above a chemical discharge pipe 121, the chemical discharge port 123 preferably does not overlap with the bubble discharge pipe 181 along the vertical direction (Z direction).

Six or more bubble discharge pipes 181 are preferably disposed in one inner tank 111. The flow rate of bubbles supplied from the bubble discharge pipe 181 is preferably 15 L/min or more for the inner tank 111. It is preferable that the bubble discharge pipes 181 are evenly disposed with respect to the substrates 20. In this case, each bubble discharge pipe 181 may supply bubbles to the phosphoric acid solution 30 at substantially the same flow rate. However, the present disclosure is not limited to this, and each bubble discharge pipe 181 may supply the bubbles to the phosphoric acid solution 30 at a different flow rate depending on its arrangement with respect to the substrates 20.

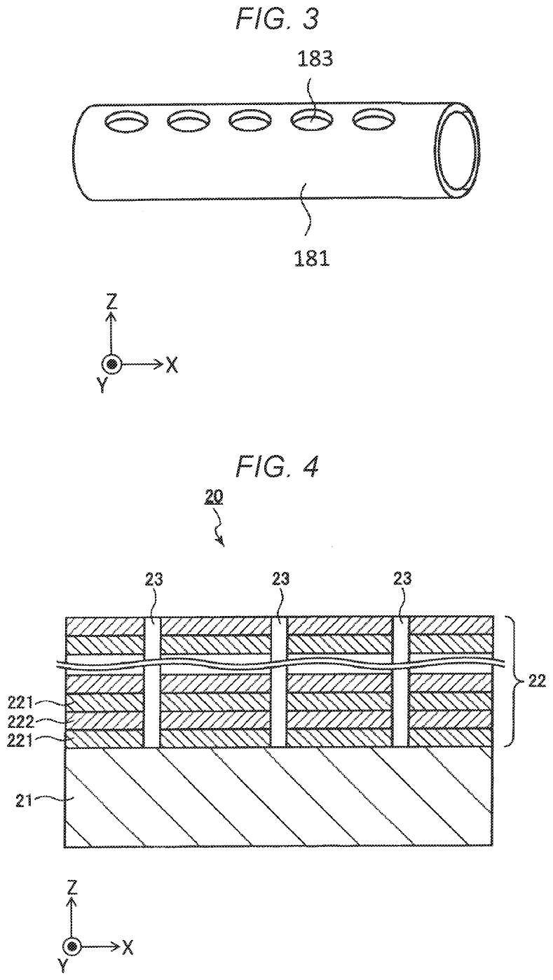

FIG. 3 is a perspective view schematically showing the structure of a bubble discharge pipe 181. Since the structure of the chemical discharge pipe 121 according to the present embodiment is basically the same as the structure of the bubble discharge pipe 181, the structure of the bubble discharge pipe 181 will be described here as an example of both pipe types. Although the cross section of the bubble discharge pipe 181 is circular in FIG. 3, the cross section of the bubble discharge pipe 181 may be semicircular with the same upper half structure as shown in FIG. 2. A plurality of bubble discharge ports 183 communicating with the inside of the inner tank 111 are provided in rows in the longitudinal direction on the outer peripheral upper surface of the bubble discharge pipe 181. The bubble discharge ports 183 are disposed at approximately equal intervals in the X direction. The shape of the bubble discharge port 183 is circular, but is not particularly limited to this. The number of bubble discharge ports 183 is preferably sixty (60) or more per bubble discharge pipe 181. The number of bubble discharge ports 183 in one inner tank 111 is preferably two-hundred forty (240) or more, more preferably two-hundred eighty (280) or more, for example. Each bubble discharge port 183 disposed on one bubble discharge pipe 181 may supply the same flow rate of bubbles to the phosphoric acid solution 30.

In the present embodiment, the bubble discharge pipe 181a disposed near the center C preferably discharges gas directed toward the center C side. It is preferable that the direction of each bubble discharge port 183a disposed in the bubble discharge pipe 181a is inclined at an angle θ toward the center C side from the vertical direction. More preferably, the bubble discharge pipe 181a discharges gas toward the center C side at an angle θ of 60° or more from the vertical direction. It is more preferable that the direction of each bubble discharge port 183a disposed in the bubble discharge pipe 181a is inclined at an angle θ of 60° or more toward the center C side from the vertical direction.

In the present embodiment, the chemical discharge pipe 121 preferably also supplies the chemical agent toward the center C side. It is preferable that the direction of each chemical discharge port 123 disposed in the chemical discharge pipe 121 is inclined toward the center C side from vertical. Here, the direction of the bubble discharge port 183 and the chemical discharge port 123 indicates the direction of the bubbles and the chemical agent from the central axis of the bubble discharge pipe 181 and the chemical discharge pipe 121 to the center of the bubble discharge port 183 and the chemical discharge port 123.

By providing the bubble discharge port 183 and the chemical discharge port 123 in this way, flow jets (depicted as arrows in FIG. 2) of the bubbles supplied by the bubble discharge pipe 181 and the phosphoric acid solution 30 supplied by the chemical discharge pipe 121 to pass between adjacent substrates 20 from the bottom portion of the inner tank 111 can be collected at the center C in the lateral direction (Y direction) of the main surface of the substrate 20 and agitated (vibrated).

Further, as shown in FIG. 2, the rectifying plates 19 are provided in the inner tank 111 between the holding member 17 and the bubble discharge pipe 181 and the chemical discharge pipe 121. The rectifying plate 19 regulates the flow formed by the bubbles supplied by the bubble discharge pipe 181 as well as the flow formed by the phosphoric acid solution 30 supplied by the chemical discharge pipe 121, and helps implement a uniform jet flow velocity distribution in the phosphoric acid solution 30 stored in the inner tank 111.

The rectifying plate 19 is disposed below the substrate 20 held by the holding member 17. The rectifying plate 19 is plate-shaped and extends in the X direction. The length of the rectifying plate 19 in the X direction may be the same as the length of the holding member 17, for example. However, without being limited to this, the rectifying plate 19 may extend from one side surface of the inner tank 111 to the opposite side surface thereof in the X direction. Two rectifying plates 19 may be disposed symmetrically in the Y direction about the center C. The two rectifying plates 19 may be disposed with an interval of 4.5 cm or less across the center C in the lateral direction (Y direction) of the main surface of the substrate 20. The rectifying plate 19 extends from one end of the chemical discharge pipe 121 to the other end of the bubble discharge pipe 181a when viewed from above. It is preferable that the rectifying plate 19 overlaps the bubble discharge pipe 181a when viewed from above. It is preferable that the rectifying plate 19 overlaps 50% or more of the chemical discharge pipe 121 when viewed from above. The rectifying plate 19 extends with an inclination with respect to the lateral direction (Y direction) of the main surface of the substrate 20. Alternatively, the rectifying plate 19 extends with an inclination with respect to the horizontal bottom surface of the inner tank 111. It is preferable that the rectifying plate 19 has a height on the side of the bubble discharge pipe 181a higher than a height on the side of the chemical discharge pipe 121. That is, it is preferable that the rectifying plate 19 has an inclination such that the height on the center C side is high relative to the opposite end of the same rectifying plate 19. The material of the rectifying plate 19 may be, for example, polytetrafluoroethylene (PTFE) or aromatic polyetherketone (PEEK). However, it is not limited to this, and the material of the rectifying plate 19 may be any material having appropriate heat resistance and chemical resistance. By having such a configuration, the rectifying plate 19 receives the flow formed by the bubbles supplied by the bubble discharge pipe 181 and the phosphoric acid solution 30 supplied by the chemical discharge pipe 121, and can provide a uniform jet flow velocity distribution in the phosphoric acid solution 30 stored in the inner tank 111.

The substrate processing apparatus according to the present embodiment implements a uniform jet flow velocity distribution in the phosphoric acid solution 30 stored in the inner tank 111 by arrangement of the flow of the bubbles and the phosphoric acid solution 30, thereby improving the stirring efficiency of the phosphoric acid solution 30.

### Substrate Processing Method

A substrate processing method using the substrate processing apparatus 1 according to the present embodiment will be described below. The substrate processing method of the present embodiment can be performed, for example, as part of a method of manufacturing a semiconductor device. FIG. 4 is a cross-sectional view of a substrate 20 to be etched. The substrate 20 is a semiconductor substrate for manufacturing a stacked memory device in which electrode layers are stacked with insulating layers therebetween.

As shown in FIG. 4, the substrate 20 comprises a silicon substrate 21 and a stacked film 22 thereon. The stacked film 22 includes silicon oxide films 221 and silicon nitride films 222 that are alternately stacked. The substrate 20 also has one or more trench 23 penetrating through the stacked film 22.

When the substrates 20 are accommodated inside the inner tank 111 on the holding member 17, the phosphoric acid solution 30 stored inside the inner tank 111 penetrates into the stacked film 22 via the trench(es) 23. Thereby, each silicon nitride film 222 is removed. At this time, the concentration of silica in the phosphoric acid solution 30 increases due to the dissolved silicon nitride film 222. An electrode layer is eventually formed in the space from which the silicon nitride film 222 has been removed in subsequent processing.

The phosphoric acid solution 30 overflowing from the inner tank 111 is collected in the outer tank 112. The phosphoric acid solution 30 collected in the outer tank 112 is sent to the heating unit 13 by the pump 15. The heating unit 13 heats the phosphoric acid solution 30. The phosphoric acid solution 30 (now heated by the heating unit 13) is then discharged into the inner tank 111 from the chemical discharge ports 123 of the chemical discharge pipes 121 by action of the pump 15. Bubbles are discharged into the inner tank 111 from the bubble discharge ports 183 of the bubble discharge pipes 181. The bubbles and the flow of the phosphoric acid solution 30 pass the rectifying plate 19 and then between the adjacent substrates 20, so that a uniform jet flow velocity distribution can be achieved in the phosphoric acid solution 30 stored in the inner tank 111.

In the substrates 20, when the amount of silicon nitride film 222 dissolved in the phosphoric acid solution 30 increases, the amount of silica dissolved in the phosphoric acid solution 30 increases. Therefore, silica may be likely to precipitate within a trench 23 or the like. On the other hand, when the concentration of silica in the phosphoric acid solution becomes low, the selection ratio of the silicon nitride film to the silicon oxide film becomes low, and the silicon oxide film may be eroded disadvantageously. By making the phosphoric acid solution 30 in which the substrate 20 is immersed uniform, the silica concentration in the phosphoric acid solution can be controlled.

The substrate processing method using the substrate processing apparatus 1 according to the present embodiment implements a uniform jet flow velocity distribution in the phosphoric acid solution 30 stored in the inner tank 111 by the flow of the bubbles and the phosphoric acid solution 30, thereby improving the stirring efficiency of the phosphoric acid solution 30.

### Second Embodiment

The configuration of the substrate processing apparatus according to the present embodiment is generally the same as the configuration of the substrate processing apparatus according to the first embodiment, except that the pointing directions of some bubble discharge ports 181 are different. The substrate processing method according to the second embodiment is otherwise the same as the substrate processing method according to the first embodiment. Aspects that differ from the configuration of the substrate processing apparatus according to the first embodiment are primarily described here.

### Substrate Processing Apparatus

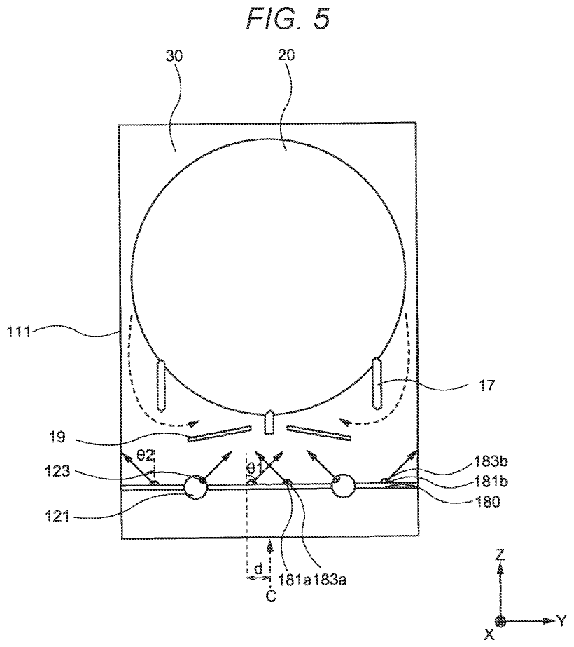

FIG. 5 is a schematic diagram showing the internal structure of the inner tank 111 according to the present embodiment. As shown in FIG. 5, the holding member 17 holds the substrate 20 inside the inner tank 111. A tube plate 180 is provided below the holding member 17. The tube plate 180 holds a bubble discharge pipes 181 (including a bubble discharge pipe 181a and a bubble discharge pipe 181b) and a chemical discharge pipe 121 facing the holding member 17 side. The rectifying plate 19 is provided between the holding member 17 and the bubble discharge pipes 181 and the chemical discharge pipes 121.

The bubble discharge pipes 181 include the bubble discharge ports 183 for supplying bubbles (gas) to stir the phosphoric acid solution 30 stored in the inner tank 111. At least one bubble discharge port 183a and at least one bubble discharge port 183b are provided. The bubble discharge pipes 181a are disposed closer to the center C than the chemical discharge pipes 121. That is, some of the bubble discharge pipes 181a may be disposed closer to the center C than the chemical discharge pipes 121. The bubble discharge pipes 181a may be disposed within a distance d of 2.5 cm from the center C in the lateral direction (Y direction). The bubble discharge pipes 181b may be disposed closer to the end side of the main surface of the substrate 20 in the lateral direction (Y direction) than the chemical discharge pipes 121.

In the second embodiment, the bubble discharge pipes 181a preferably discharges gas toward the center C side. It is preferable that the direction of each bubble discharge port 183a disposed in the bubble discharge pipe 181a is inclined at an angle θ1 toward the center C side from the vertical direction. More preferably, the bubble discharge pipe 181a discharges gas toward the center C side at an angle θ1 of 60° or more from the vertical direction. It is more preferable that the direction of each bubble discharge port 183a disposed in the bubble discharge pipe 181a is inclined at an angle θ1 of 60° or more toward the center C side from the vertical direction.

The bubble discharge pipe 181b preferably discharges gas outwards from the center C side in the Y direction. It is preferable that the direction of each bubble discharge port 183b disposed in the bubble discharge pipe 181b is inclined at an angle θ2 from the vertical direction outwardly from the center C. More preferably, the bubble discharge pipe 181b discharges gas at an angle θ2 of 30° or more from the vertical direction. It is more preferable that the direction of each bubble discharge port 183b disposed in the bubble discharge pipe 181b is inclined at an angle θ2 of 30° or more from the vertical direction outwardly in the Y direction from the center C.

In the second embodiment, the chemical discharge pipe 121 preferably supplies the chemical agent toward the center C side in the lateral direction (Y direction). It is preferable that the direction of each chemical discharge port 123 disposed in the chemical discharge pipe 121 is inclined toward the center C side. Here, the direction of the bubble discharge port 183 and the chemical discharge port 123 indicates the direction from the central axis of the bubble discharge pipe 181 and the chemical discharge pipe 121 to the center of the bubble discharge port 183 and the chemical discharge port 123.

By providing the bubble discharge port 183a, the bubble discharge port 183b, and the chemical discharge port 123 in this way, the jets (see the arrows in FIG. 5) of the bubbles supplied by the bubble discharge pipes 181a and 181b and the phosphoric acid solution 30 supplied by the chemical discharge pipe 121 can be collected at the center C in the lateral direction (Y direction) of the main surface of the substrate 20 and vibrated. Further, the direction of the bubble jets supplied from the bubble discharge pipe 181b can be switched to the lateral direction (Y direction) of the main surface to form circulation flows that circulate on the rectifying plate 19 (see the dotted arrows in FIG. 5). Further, by forming a circulation flow, the jets (see the arrows in FIG. 5) of the bubbles supplied by the bubble discharge pipes 181a and 181b and the phosphoric acid solution 30 supplied by the chemical discharge pipe 121 can be further vibrated in the lateral direction (Y direction) of the main surface of the substrate 20.

According to the substrate processing apparatus according to the present embodiment, a uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

### Third Embodiment

The configuration of the substrate processing apparatus according to the third embodiment is the same as the configuration of the substrate processing apparatus according to the first embodiment, except that the directions of some bubble discharge ports are different. The substrate processing method according to the third embodiment is the same as the substrate processing method according to the first embodiment.

### Substrate Processing Apparatus

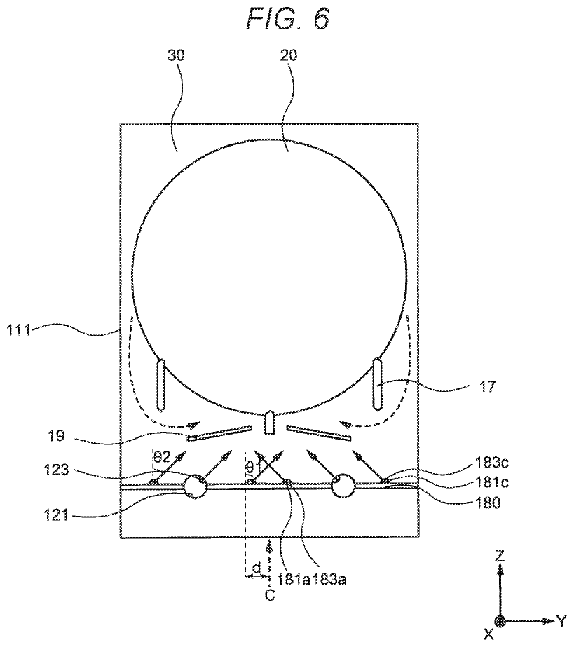

FIG. 6 is a schematic diagram showing the internal structure of the inner tank 111 according to the present embodiment. As shown in FIG. 6, the holding member 17 holds the substrate 20 inside the inner tank 111. A tube plate 180 is provided below the holding member 17 (on the bottom surface side of the inner tank 111). The tube plate 180 holds a bubble discharge pipe 181 (referred to as the bubble discharge pipe 181 when a bubble discharge pipe 181a and the bubble discharge pipe 181c are not distinguished) and a chemical discharge pipe 121 on the surface (upper surface) on the holding member 17 side. The rectifying plate 19 is provided between the holding member 17 and the bubble discharge pipe 181 and the chemical discharge pipe 121.

The bubble discharge pipes 181 include the bubble discharge ports 183 for supplying bubbles (gas) to stir the phosphoric acid solution 30. The bubble discharge ports 183 include at least one bubble discharge port 183a and at least one bubble discharge port 183c. The plurality of bubble discharge pipes 181 are arranged in rows spaced from each other in the lateral direction (Y direction). The plurality of bubble discharge pipes 181 may be disposed symmetrically in the Y direction about the center C in the lateral direction (Y direction). Some of the bubble discharge pipes 181a may be disposed closer to the center C side. Some of the bubble discharge pipes 181a may be disposed within a distance d of 2.5 cm from the center C in the lateral direction (Y direction). Some of the bubble discharge pipes 181c may be disposed closer to the end side of the main surface of the substrate 20 in the lateral direction (Y direction) than the chemical discharge pipe 121.

In the third embodiment, the bubble discharge pipe 181a preferably discharges gas toward the center C side. It is preferable that the direction of each bubble discharge port 183a disposed in the bubble discharge pipe 181a is inclined at an angle θ1 toward the center C side from the vertical direction. More preferably, the bubble discharge pipe 181a discharges gas toward the center C side at an angle θ1 of 60° or more from the vertical direction. It is more preferable that the direction of each bubble discharge port 183a disposed in the bubble discharge pipe 181a is inclined at an angle θ1 of 60° or more toward the center C side from the vertical direction.

The bubble discharge pipe 181c preferably discharges gas toward the center C side. It is preferable that the direction of each bubble discharge port 183c disposed in the bubble discharge pipe 181c is inclined at an angle θ2 toward the center C side from the vertical direction. More preferably, the bubble discharge pipe 181c discharges gas toward the center C side at an angle θ2 of 30° or more from the vertical direction. It is more preferable that the direction of each bubble discharge port 183c disposed in the bubble discharge pipe 181c is inclined at an angle θ2 of 30° or more toward the center C side from the vertical direction.

In the third embodiment, the chemical discharge pipe 121 preferably supplies the chemical agent toward the center C. It is preferable that the direction of each chemical discharge port 123 disposed in the chemical discharge pipe 121 is inclined toward the center C side. Here, the direction of the bubble discharge port 183 and the chemical discharge port 123 indicates the direction from the central axis of the bubble discharge pipe 181 and the chemical discharge pipe 121 to the center of the bubble discharge port 183 and the chemical discharge port 123.

By providing the bubble discharge port 183a, the bubble discharge port 183c, and the chemical discharge port 123 in this way, the jets (see the arrows in FIG. 6) of the bubbles supplied by the bubble discharge pipes 181a and 181c and the phosphoric acid solution 30 supplied by the chemical discharge pipe 121 can be collected at the center C and vibrated. Further, the direction of the bubble jets supplied from the bubble discharge pipe 181c can be switched in the lateral direction (Y direction) to form stronger circulation flows (see the dotted arrows in FIG. 6) that circulates above the rectifying plates 19. Further, by forming a circulation flow, the jets (see the arrows in FIG. 6) of the bubbles supplied by the bubble discharge pipe 181a and the bubble discharge pipe 181c and the phosphoric acid solution 30 supplied by the chemical discharge pipe 121 can be further mixed in the lateral direction (Y direction).

According to the substrate processing apparatus according to the third embodiment, more uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

### Fourth Embodiment

The configuration of the substrate processing apparatus according to the fourth embodiment is the same as the configuration of the substrate processing apparatus according to the first embodiment, except for having spacers. The substrate processing method according to the fourth embodiment is the same as the substrate processing method according to the first embodiment.

### Substrate Processing Apparatus

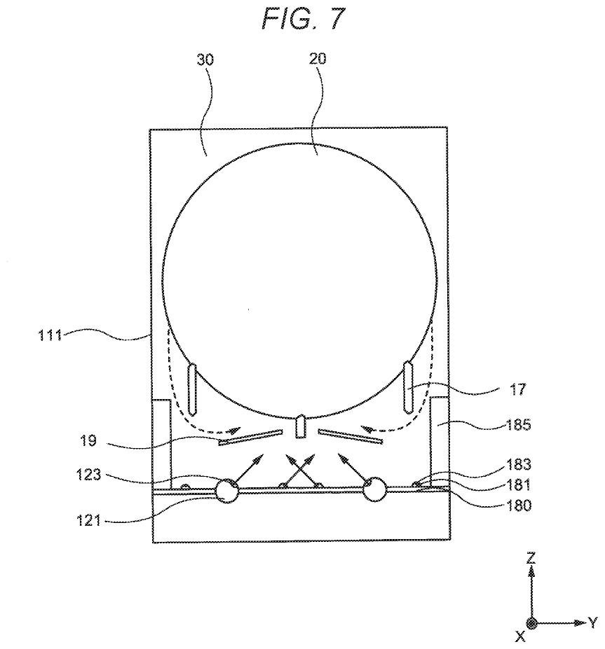

FIG. 7 is a schematic diagram showing the internal structure of the inner tank 111 according to the present embodiment. As shown in FIG. 7, the holding member 17 holds the substrate 20 inside the inner tank 111. A tube plate 180 is provided below the holding member 17 (on the bottom surface side of the inner tank 111). The tube plate 180 holds the bubble discharge pipe 181, the chemical discharge pipe 121, and the spacer 185, on the surface (upper surface) on the holding member 17 side. The rectifying plate 19 is provided between the holding member 17 and the bubble discharge pipe 181 and the chemical discharge pipe 121.

In the present embodiment, the spacer 185 may be disposed along the bottom portion inner surface of the inner tank 111 to protrude inward of the inner tank 111. In the present embodiment, the spacer 185 is of a square tube shape having an inner surface substantially parallel to the inner surface of the inner tank 111. However, without being limited to this, the inner surface of the spacer 185 may have an angle with the inner surface of the inner tank 111. In this case, the spacer 185 may protrude to the inside of the inner tank 111 toward the bottom side of the inner tank 111. The tube plate 180 and the spacer 185 may be integrated or separate. However, without being limited to this, when the tube plate 180 is not present, the spacer 185 may be disposed directly on the bottom of the inner tank 111. The upper end of the spacer 185 is preferably lower than the center of the substrate 20 in the vertical direction (Z direction). The material of the spacer 185 may be, for example, polytetrafluoroethylene (PTFE) or aromatic polyetherketone (PEEK). However, it is not limited to this, and the material of the spacer 185 may be any resin having heat resistance and chemical resistance.

By providing the spacer 185 in this way, the direction of the jets of bubbles supplied from the bubble discharge pipe 181 is switched to the lateral direction (Y direction) of the main surface, and the intensity of the circulation flow (see the dotted arrows in FIG. 7) that circulates on the rectifying plate 19 can be controlled.

According to the substrate processing apparatus according to the present embodiment, more uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

### Fifth Embodiment

The configuration of the substrate processing apparatus according to the present embodiment is the same as the configuration of the substrate processing apparatus according to the first embodiment, except that the heights of some bubble discharge ports are different. The substrate processing method according to the present embodiment is the same as the substrate processing method according to the first embodiment.

### Substrate Processing Apparatus

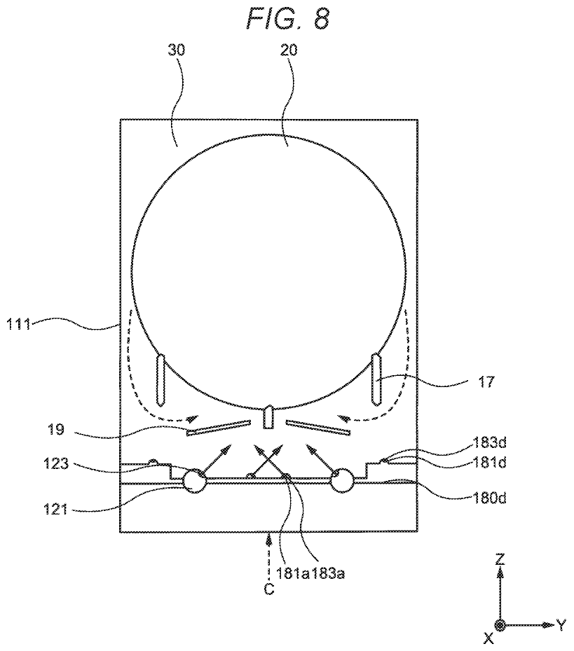

FIG. 8 is a schematic diagram showing the internal structure of the inner tank 111 according to the present embodiment. As shown in FIG. 8, the holding member 17 holds the substrate 20 inside the inner tank 111. A tube plate 180d is provided below the holding member 17 (on the bottom surface side of the inner tank 111). The tube plate 180d is a plate-like member and is disposed substantially horizontally on the bottom portion of the inner tank 111. The tube plate 180d holds a bubble discharge pipe 181 (referred to as the bubble discharge pipe 181 when a bubble discharge pipe 181a and the bubble discharge pipe 181d are not distinguished) and a chemical discharge pipe 121 on the surface (upper surface) on the holding member 17 side. The rectifying plate 19 is provided between the holding member 17 and the bubble discharge pipe 181 and the chemical discharge pipe 121.

The bubble discharge pipe 181 includes the bubble discharge port 183 for supplying bubbles (gas) to stir the phosphoric acid solution 30 stored in the inner tank 111 (referred to as the bubble discharge port 183 when the bubble discharge port 183a and the bubble discharge port 183d are not distinguished). The plurality of bubble discharge pipes 181 are arranged in rows spaced from each other in the lateral direction (Y direction). The plurality of bubble discharge pipes 181 may be disposed symmetrically in the Y direction about the center C in the lateral direction (Y direction). Some of the bubble discharge pipes 181a may be disposed closer to the center C than the chemical discharge pipe 121. Some of the bubble discharge pipes 181a may be disposed closer to the center C side of the bottom surface of the inner tank 111 in the lateral direction (Y direction) than the chemical discharge pipe 121. Some of the bubble discharge pipes 181a may be disposed within a distance d of 2.5 cm from the center C in the lateral direction (Y direction). Some of the bubble discharge pipes 181d may be disposed closer to the end side of the main surface of the substrate 20 in the lateral direction (Y direction) than the chemical discharge pipe 121. Some of the bubble discharge pipes 181d may be disposed at a higher position in the vertical direction (Z direction) than some of the bubble discharge pipes 181a and chemical discharge pipes 121. Some of the bubble discharge pipes 181d may be disposed at a position lower than the rectifying plate 19 in the vertical direction (Z direction).

The surface (upper surface) of the tube plate 180d on the side of the holding member 17 is such that the end in the lateral direction (Y direction) from the chemical discharge pipe 121 is higher in the vertical direction (Z direction) than the center C side end from the chemical discharge pipe 121. The surface (lower surface) opposite to the upper surface of the tube plate 180d is flat. However, without being limited thereto, as long as the positional relationship between some of the bubble discharge pipes 181a and some of the bubble discharge pipes 181d is satisfied, the shape of the tube plate 180d is not particularly limited and the tube plate 180d may be omitted.

By providing the bubble discharge ports 183a and 183d, and the chemical discharge port 123 in this way, the jets (see the arrows in FIG. 8) of the bubbles supplied by the bubble discharge pipes 181a and 181d and the phosphoric acid solution 30 supplied by the chemical discharge pipe 121 can be collected at the center C in the lateral direction (Y direction) and mixed. Further, the direction of the bubble jets supplied from the bubble discharge pipe 181d can be switched to the lateral direction (Y direction) of the main surface to form strong circulation flows that circulate on the rectifying plate 19 (see the dotted arrows in FIG. 8). Further, by forming a circulation flow, the jets (see the arrows in FIG. 8) of the bubbles supplied by the bubble discharge pipe 181a and the bubble discharge pipe 181d and the phosphoric acid solution 30 supplied by the chemical discharge pipe 121 can be further mixed in the lateral direction (Y direction).

According to the substrate processing apparatus according to the fifth embodiment, more uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

### Sixth Embodiment

The configuration of the substrate processing apparatus according to the present embodiment is the same as the configuration of the substrate processing apparatus according to the first embodiment, except that the lengths of the holding members are different. The substrate processing method according to the present embodiment is the same as the substrate processing method according to the first embodiment.

### Substrate Processing Apparatus

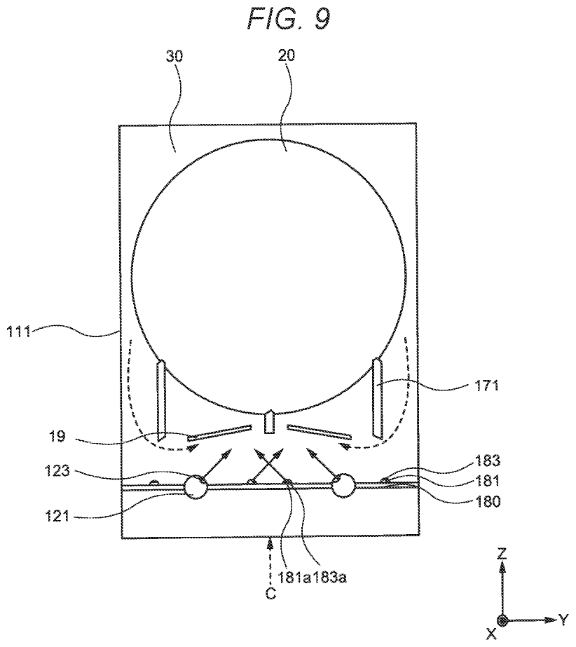

FIG. 9 is a schematic diagram showing the internal structure of the inner tank 111 according to the present embodiment. As shown in FIG. 9, the holding member 171 holds the substrate 20 inside the inner tank 111. A tube plate 180 is provided below the holding member 171 (on the bottom surface side of the inner tank 111). The tube plate 180 holds a bubble discharge pipe 181 (referred to as the bubble discharge pipe 181 when a bubble discharge pipe 181a and the other bubble discharge pipe 181 are not distinguished) and a chemical discharge pipe 121 on the surface (upper surface) on the holding member 171 side. The rectifying plate 19 is provided between the holding member 171 and the bubble discharge pipe 181 and the chemical discharge pipe 121.

In the present embodiment, the lower end of the holding member 171 extends in the vertical direction (Z direction). The lower end of the holding member 171 may be, for example, at the same height as the height of the rectifying plate 19 in the vertical direction (Z direction). However, without being limited to this, the lower end of the holding member 171 may be lower than the rectifying plate 19 in the vertical direction (Z direction). By configuring the holding member 171 in this way, the direction of the bubble jets supplied from the bubble discharge pipe 181 can be switched to the lateral direction (Y direction) of the main surface to form circulation flows that circulate under the rectifying plate 19 (see the dotted arrows in FIG. 9). Further, by forming a circulation flow, the jets (see the arrows in FIG. 9) of the bubbles supplied by the bubble discharge pipe 181 and the phosphoric acid solution 30 supplied by the chemical discharge pipe 121 can be further mixed in the lateral direction (Y direction).

According to the substrate processing apparatus according to the sixth embodiment, a uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

### Seventh Embodiment

The configuration of the substrate processing apparatus according to the present embodiment is the same as the configuration of the substrate processing apparatus according to the first embodiment, except that the lengths of the holding members are different. The substrate processing method according to the present embodiment is the same as the substrate processing method according to the first embodiment.

### Substrate Processing Apparatus

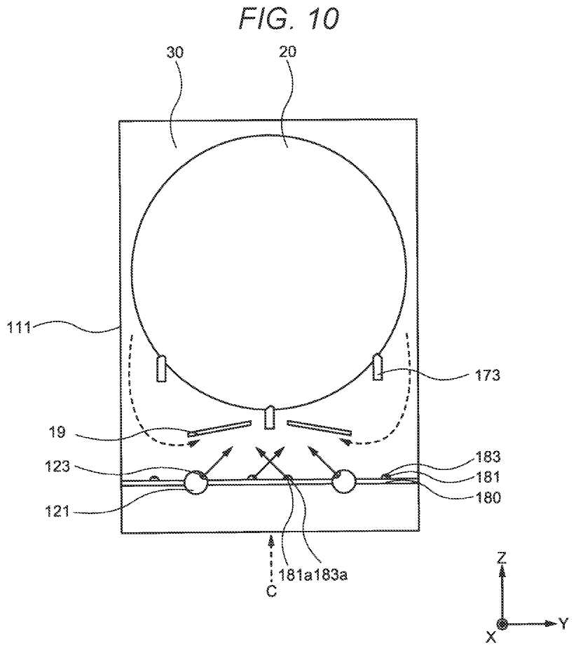

FIG. 10 is a schematic diagram showing the internal structure of the inner tank 111 according to the present embodiment. As shown in FIG. 10, the holding member 173 holds the substrate 20 inside the inner tank 111. A tube plate 180 is provided below the holding member 173 (on the bottom surface side of the inner tank 111). The tube plate 180 holds a bubble discharge pipe 181 (referred to as the bubble discharge pipe 181 when a bubble discharge pipe 181a and the other bubble discharge pipe 181 are not distinguished) and a chemical discharge pipe 121 on the surface (upper surface) on the holding member 173 side. The rectifying plate 19 is provided between the holding member 173 and the bubble discharge pipe 181 and the chemical discharge pipe 121.

In the present embodiment, the lower end of the holding member 173 is cut in the vertical direction (Z direction). The lower end of the holding member 173 may be higher than the lower end of the substrate 20, for example, in the vertical direction (Z direction). By configuring the holding member 173 in this way, the direction of the bubble jets supplied from the bubble discharge pipe 181 can be switched to the lateral direction (Y direction) of the main surface to form strong circulation flows that circulate under the rectifying plate 19 (see the dotted arrows in FIG. 10). Further, by forming a circulation flow, the jets (see the arrows in FIG. 10) of the bubbles supplied by the bubble discharge pipe 181 and the phosphoric acid solution 30 supplied by the chemical discharge pipe 121 can be further mixed in the lateral direction (Y direction).

According to the substrate processing apparatus according to the seventh embodiment, more uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

### Eighth Embodiment

The configuration of the substrate processing apparatus according to the eighth embodiment is the same as the configuration of the substrate processing apparatus according to the first embodiment, except for having a second rectifying plate (190). The substrate processing method according to the eighth embodiment is the same as the substrate processing method according to the first embodiment.

### Substrate Processing Apparatus

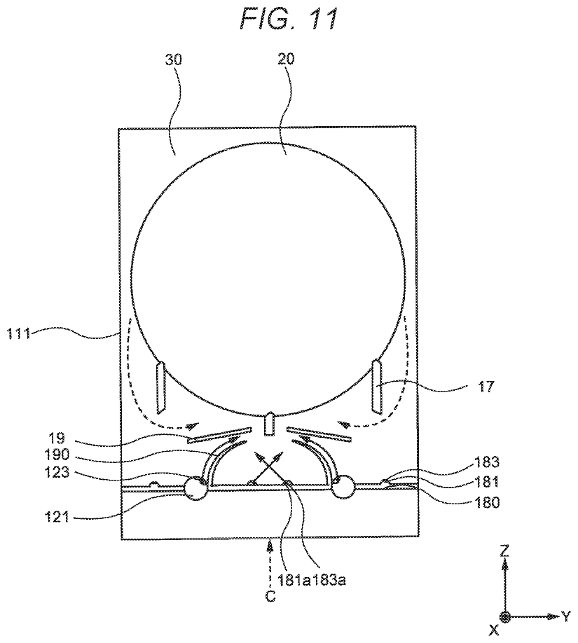

FIG. 11 is a schematic diagram showing the internal structure of the inner tank 111 according to the eighth embodiment. As shown in FIG. 11, the holding member 17 holds the substrate 20 inside the inner tank 111. A tube plate 180 is provided below the holding member 17 (on the bottom surface side of the inner tank 111). The tube plate 180 holds a bubble discharge pipe 181 (including at least one bubble discharge pipe 181a), the chemical discharge pipes 121, and the second rectifying plate 190 on the surface (upper surface) on the holding member 17 side. A first rectifying plate 19 is provided between the holding member 17 and the bubble discharge pipes 181 and the chemical discharge pipes 121.

In the eighth embodiment, the second rectifying plate 190 is disposed below the first rectifying plate 19. The second rectifying plate 190 extends in the X direction. The length of the second rectifying plate 190 in the X direction may be the same as the length of the holding member 17, for example. However, without being limited to this, the second rectifying plate 190 may extend from one side surface of the inner tank 111 to the opposite side surface thereof in the X direction. Two second rectifying plates 190 may be disposed symmetrically in the Y direction from the center C. The two second rectifying plates 190 may be disposed with an interval of 4.5 cm or less across the center C in the lateral direction (Y direction). The second rectifying plate 190 extends from one end of the chemical discharge pipe 121 to the other end of the bubble discharge pipe 181a when viewed from above.

The second rectifying plate 190 extends with an inclination with respect to the lateral direction (Y direction) of the main surface of the substrate 20. That is, the second rectifying plate 190 extends with an inclination with respect to a direction horizontal to the bottom surface of the inner tank 111. It is preferable that the second rectifying plate 190 has an inclination such that the height on the side of the bubble discharge pipe 181a is higher than the height on the side of the chemical discharge pipe 121. That is, it is preferable that the second rectifying plate 190 has an inclination such that the height on the center C side is high. Further, it is preferable that the second rectifying plate 190 is convex upward and curved. The second rectifying plate 190 is preferably disposed adjacent to the center C side of the chemical discharge pipe 121. By providing the second rectifying plate 190 adjacent to the center C side of the chemical discharge pipe 121, the jet of the phosphoric acid solution 30 supplied by the chemical discharge pipe 121 (see the arrows in FIG. 11) is curved along the second rectifying plate 190 due to the Coanda effect. By configuring the second rectifying plate 190 in this way, the jets (see the arrows in FIG. 11) of the bubbles supplied by the bubble discharge pipe 181a and the bubble discharge pipe 181 and the phosphoric acid solution 30 supplied by the chemical discharge pipe 121 can be mixed in the lateral direction (Y direction).

According to the substrate processing apparatus according to the eighth embodiment, more uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

### Modification Example 1

The configuration of the substrate processing apparatus according to the present modification example (Example 1) is the same as the configuration of the substrate processing apparatus according to the first embodiment, except that there is no rectifying plate 19. The substrate processing method according to the modification is the same as the substrate processing method according to the first embodiment.

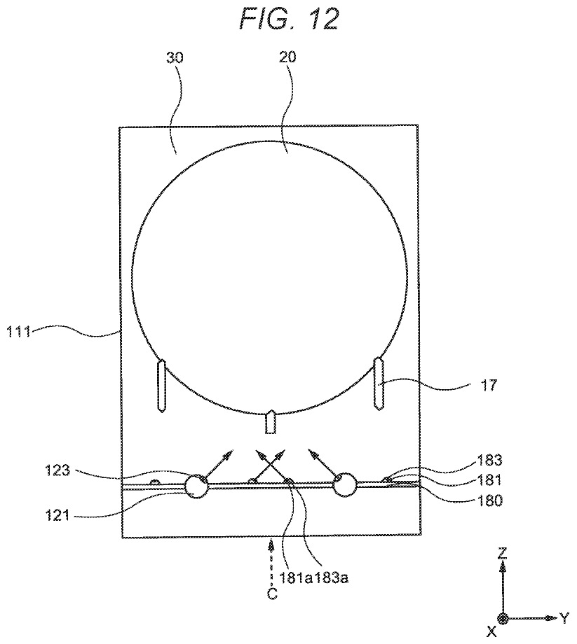

FIG. 12 is a schematic diagram showing an internal structure of an inner tank 111 according to this modification example (Example 1). As shown in FIG. 12, the rectifying plate 19 is not disposed in the substrate processing apparatus. In the substrate processing apparatus according to Example 1, the jets (see the arrows in FIG. 12) are generated in the lateral direction (Y direction) by the arrangement of the bubble discharge pipe 181 and the chemical discharge pipe 121 and the directions of the bubble discharge port 183 and the chemical discharge ports 123. Such flows can be collected at the center C (in the Y direction) and mixed. According to the substrate processing apparatus 1, a uniform jet flow velocity distribution in the phosphoric acid solution 30 stored in the inner tank 111 may be achieved by the flows of the bubbles and the phosphoric acid solution 30 even without the presence of a rectifying plate 19 or the like, thereby improving the stirring efficiency of the phosphoric acid solution 30.

### Modification Example 2

The configuration of a substrate processing apparatus according to the present modification example (Example 2) is the same as the configuration of the substrate processing apparatus according to the first embodiment. A substrate processing method according to the present example is the same as the substrate processing method according to the first embodiment, except for the timings of supplying the phosphoric acid solution from the chemical discharge pipe and the bubbles from the bubble discharge pipe.

In this modification example (Example 2), the timing when the phosphoric acid solution is supplied from the chemical discharge pipe 121 and the timing when the bubbles are discharged from the bubble discharge pipe 181 are shifted in time and offset in the lateral direction (Y direction). For example, the flow rate of the phosphoric acid solution 30 supplied from the plurality of chemical discharge pipes 121 may have periodic temporal changes. In this case, the change in flow rate may be controlled by a pump or the like. It is preferable that the flow rate of the phosphoric acid solution 30 supplied from each of the plurality of chemical discharge pipes 121 can be independently controlled. The cycles of the flow rates of the phosphoric acid solution 30 supplied from the left and right chemical discharge pipes 121 in the lateral direction (Y direction) may be in opposite phase relationship.

By controlling the flow rate of the phosphoric acid solution 30 in this manner, the jets (see the arrows in FIG. 2) of the bubbles supplied by the bubble discharge pipe 181a and the bubble discharge pipe 181 and the phosphoric acid solution 30 supplied by the chemical discharge pipe 121 can be mixed in the lateral direction (Y direction).

For example, the ON/OFF timing of the bubbles supplied from the plurality of bubble discharge pipes 181 may have periodic temporal changes. In this case, the change in the ON/OFF timing of the bubbles may be controlled by a valve or the like. It is preferable that the ON/OFF timing of the bubbles supplied from each of the plurality of bubble discharge pipes 181 can be independently controlled. The cycles of ON/OFF timings of the bubbles supplied from the left and right bubble discharge pipes 181 in the lateral direction (Y direction) may be in opposite phase relationship.

By controlling the ON/OFF timing of the bubbles in this way, the jets (see the arrows in FIG. 2) of the bubbles supplied by the bubble discharge pipe 181a and the bubble discharge pipe 181 and the phosphoric acid solution 30 supplied by the chemical discharge pipe 121 can be mixed in the lateral direction (Y direction).

According to the substrate processing apparatus according to Example 2, more uniform jet flow velocity distribution in the phosphoric acid solution 30 stored in the inner tank 111 is achieved by the flows of the bubbles and the phosphoric acid solution 30, thereby further improving the stirring efficiency of the phosphoric acid solution 30.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus, comprising:
a treatment tank for storing a chemical solution for treating a substrate immersed in the treatment tank;
a holder configured to hold the substrate while in the treatment tank;
a chemical discharge pipe in the treatment tank below a position of the holder, the chemical discharge pipe for supplying the chemical solution to the treatment tank;
a first bubble discharge pipe in the treatment tank below the position of the holder, the first bubble discharge pipe being closer along a first horizontal direction to a centerline of the treatment tank than is the chemical discharge pipe and configured for discharging a gas into the chemical solution; and
a rectifying plate in the treatment tank below the position of the holder, rectifying plate extending from a position above the chemical discharge pipe to a position above the first bubble discharge pipe at an incline with respect to the first direction horizontal.

2. The substrate processing apparatus according to claim 1, wherein a height of the rectifying plate from a bottom surface of the treatment tank is greater at the position above the first bubble discharge pipe side than a height of the rectifying plate from the bottom surface of the treatment tank at the position above the chemical discharge pipe.

3. The substrate processing apparatus according to claim 1, wherein the rectifying plate is directly above the first bubble discharge pipe and the chemical discharge pipe in a vertical direction perpendicular to a bottom surface of the treatment tank.

4. The substrate processing apparatus according to claim 1, wherein the chemical discharge pipe has a discharge port angled towards the centerline and upwards towards the holder.

5. The substrate processing apparatus according to claim 1, wherein the first bubble discharge pipe has a discharge port angled towards the centerline and upwards towards the holder.

6. The substrate processing apparatus according to claim 1, wherein the first bubble discharge pipe discharges the gas toward the centerline at an angle of at least 60° from a vertical direction perpendicular a bottom surface of the treatment tank.

7. The substrate processing apparatus according to claim 1, wherein the first bubble discharge pipe is disposed within 2.5 centimeters (cm) from the centerline along the first horizontal direction.

8. The substrate processing apparatus according to claim 1, wherein the rectifying plate overlaps the first bubble discharge pipe when viewed from above.

9. The substrate processing apparatus according to claim 1, wherein the rectifying plate overlaps 50% or more of the chemical discharge pipe when viewed from above.

10. The substrate processing apparatus according to claim 1, wherein a second bubble discharge pipe in the treatment tank below the position of the holder, the second bubble discharge pipe being closer along the first horizontal direction to a wall of the treatment tank than is the chemical discharge pipe and configured for discharging the gas into the chemical solution.

11. The substrate processing apparatus according to claim 10, wherein the second bubble discharge pipe discharges the gas toward the centerline.

12. The substrate processing apparatus according to claim 10, wherein the second bubble discharge pipe discharges the gas away from the centerline toward the wall.

13. A substrate processing method, comprising:
placing a substrate in a holder configured to hold the substrate while in a treatment tank;
immersing the substrate in a chemical solution in the treatment tank, the treatment tank being adapted for storing the chemical solution and including therein:
a chemical discharge pipe below a position of the holder,
a first bubble discharge pipe below the position of the holder, the first bubble discharge pipe being closer along a first horizontal direction to a centerline of the treatment tank than is the chemical discharge pipe, and
a rectifying plate below the position of the holder, rectifying plate extending from a position above the chemical discharge pipe to a position above the first bubble discharge pipe at an incline with respect to the first direction horizontal; and
discharging bubbles from the first bubble discharge pipe and supplying the chemical solution from the chemical discharge pipe.

14. The substrate processing method according to claim 13, wherein the chemical discharge pipe has a discharge port angled towards the centerline and upwards towards the holder.

15. The substrate processing method according to claim 13, wherein the first bubble discharge pipe has a discharge port angled towards the centerline and upwards towards the holder.

16. The substrate processing method according to claim 13, wherein the treatment tank further includes therein a second bubble discharge pipe below the position of the holder, the second bubble discharge pipe being closer along the first horizontal direction to a wall of the treatment tank than is the chemical discharge pipe and configured for discharging the gas into the chemical solution.

17. The substrate processing method according to claim 16, wherein the second bubble discharge pipe discharges the gas toward the centerline.

18. A semiconductor device manufacturing method, comprising:
preparing a substrate;
placing the substrate in a holder configured to hold the substrate while in a treatment tank;
immersing the substrate in a chemical solution in the treatment tank, the treatment tank being adapted for storing the chemical solution and including therein:
a chemical discharge pipe below a position of the holder,
a first bubble discharge pipe below the position of the holder, the first bubble discharge pipe being closer along a first horizontal direction to a centerline of the treatment tank than is the chemical discharge pipe, and
a rectifying plate below the position of the holder, rectifying plate extending from a position above the chemical discharge pipe to a position above the first bubble discharge pipe at an incline with respect to the first direction horizontal; and
discharging bubbles from the first bubble discharge pipe and supplying the chemical solution from the chemical discharge pipe.

19. The semiconductor device manufacturing method according to claim 18, wherein the substrate is a semiconductor wafer.

20. The semiconductor device manufacturing method according to claim 19, wherein
the semiconductor wafer has formed thereon a stacked body in which layers of silicon nitride and silicon oxide are alternately formed,
the chemical solution is a phosphoric acid solution, and
the gas comprises nitrogen.
